(19) United States
(12) Patent Application Publication
(10) Pub. No.: US 2011/0136291 A1
(43) Pub. Date: Jun. 9, 2011

(54) MANUFACTURING METHOD OF A SOLID-STATE IMAGE PICKUP APPARATUS

(75) Inventors: Junji Iwata, Yokohama-shi (JP); Takeshi Ichikawa, Hachioji-shi (JP)

(73) Assignee: CANON KABUSHIKI KAISHA, Tokyo (JP)

(21) Appl. No.: 12/951,228

(22) Filed: Nov. 22, 2010

(30) Foreign Application Priority Data
Dec. 7, 2009 (JP) 2009-278009

(51) Int. Cl. H01L 31/00

(52) U.S. Cl. 438/73; 257/E31.001

(57) ABSTRACT

Provided is a manufacturing method of a solid-state image pickup apparatus including: a step of forming a first semiconductor region of a first conductivity type in a semiconductor substrate, according to an ion implantation method from a first surface of the semiconductor substrate; a step of forming a plurality of photoelectric conversion regions between the first semiconductor region and the first surface of the semiconductor substrate; a first removing step by polishing the semiconductor substrate from a second surface of the semiconductor substrate; and a second removing step by reducing a thickness of the semiconductor substrate from the second surface of the semiconductor substrate, in a speed lower than that of the first removing step, after the first removing step, in which the second removing step continues until the first semiconductor region is exposed.

### BACKGROUND OF THE INVENTION

1. Field of the Invention

The present invention relates to a manufacturing method of a back-illuminated solid-state image pickup apparatus.

2. Description of the Related Art

In recent years, in order to realize a solid-state image pickup apparatus having higher sensitivity, there has been proposed a back-illuminated solid-state image pickup apparatus in which a back surface opposite to a front surface having wiring formed thereon is used as a light incident side. A semiconductor substrate using a silicon bulk wafer, an epitaxial substrate obtained by forming, on a silicon semiconductor substrate, an epitaxial layer for forming thereon a photodiode, or an SOI substrate is used as a substrate for forming thereon the back-illuminated solid-state image pickup apparatus.

As a manufacturing method of the back-illuminated solid-state image pickup apparatus using a semiconductor substrate, there has been disclosed a method including: forming, in a part of the semiconductor substrate, an etching end detection portion of a buried layer of a material different from that of the semiconductor substrate; detecting exposure of the etching end detection portion; and thereby ending reducing a thickness (see Japanese Patent Application Laid-Open No. 2005-353996). Specifically, first, a silicon oxide film is buried from a front surface of the substrate into an imaging region and a region apart from a peripheral circuit portion which are a part of the semiconductor substrate. Next, the semiconductor substrate is polished from a back surface of the substrate according to a mechanical polishing process or a combination of the mechanical polishing process and a CMP process, and a plasma etching process is further performed thereon. Then, a change in light emission intensity when the silicon oxide film is exposed is detected, and reducing the thickness is ended. In addition, U.S. Patent Application No. 2006/0006488 has disclosed that a photodiode and the like are formed on an epitaxial layer which is formed on a substrate, an opposite side of the substrate is ground by a grinder, and then a wet etching process is performed thereon.

In addition, there has been disclosed that a P⁺ layer is formed on a semiconductor substrate, a p epitaxial layer, an n epitaxial layer, and the like are formed on the P⁺ layer, and the P⁺ layer is used as an etching stop layer (see Japanese Patent Application Laid-Open No. 2005-150521).

### SUMMARY OF THE INVENTION

However, in the conventional manufacturing methods of the back-illuminated solid-state image pickup apparatus, the throughput of a manufacturing process and the planarization of the back surface used as a light receiving surface are not sufficient.

In the manufacturing method of the solid-state image pickup apparatus according to Japanese Patent Application Laid-Open No. 2005-353996, the silicon oxide film for detecting an etching end is formed by forming an opening from the front surface of the silicon substrate and burying the silicon oxide film into the formed opening, and hence the manufacturing throughput is low. In addition, although the change in light emission intensity during the plasma etching process is detected, to thereby detect the etching end, because the silicon oxide film buried into the silicon substrate exists in a limited portion within a plane of the silicon substrate, the change in light emission intensity when the silicon oxide film is exposed is small. Therefore, the accuracy of detecting the etching end is not sufficient. Moreover, in the case where a uniform impurity concentration region of the silicon substrate is subjected to the plasma etching process, a partial difference in etching rate occurs in a surface subjected to the plasma etching process, and hence the planarization of the surface when the etching process is ended is not sufficient.

In addition, in the manufacturing method of the solid-state image pickup apparatus according to Japanese Patent Application Laid-Open No. 2005-150521, the epitaxial layers are formed, and hence the manufacturing throughput is low. Further, in one wet etching process on the silicon substrate, if an etching rate is high, it is difficult to obtain a satisfactory planarization of an etched surface, so that there is no choice but to make the etching rate slower in order to obtain the satisfactory planarization. Therefore, it is difficult to fulfill at the same time both of the manufacturing throughput and the planarization of the surface when the etching process is ended.

The present invention has been made in order to solve the above-mentioned problems of the conventional configurations, and therefore has an object to realize an inexpensive manufacturing method of a solid-state image pickup apparatus capable of obtaining an excellent image. In order to achieve the above object, the present invention provides a manufacturing method of a solid-state image pickup apparatus comprising: a step of forming a first semiconductor region of a first conductivity type in a semiconductor substrate, according to an ion implantation method from a first surface of the semiconductor substrate; a step of forming a plurality of photoelectric conversion regions between the first semiconductor region and the first surface of the semiconductor substrate; a first removing step by polishing the semiconductor substrate from a second surface of the semiconductor substrate; and a second removing step by reducing a thickness of the semiconductor substrate from the second surface of the semiconductor substrate, in a speed lower than that of the first removing step, after the first removing step, wherein the second removing step continues at least before the first semiconductor region is exposed.

According to the manufacturing method of the solid-state image pickup apparatus of the present invention, it is possible to provide a manufacturing method of a solid-state image pickup apparatus capable of enhancing the manufacturing throughput and enhancing the planarization of the back surface of the semiconductor substrate which is used as a light incident side.

Further features of the present invention will become apparent from the following description of exemplary embodiments with reference to the attached drawings.

### BRIEF DESCRIPTION OF THE DRAWINGS

FIGS. 1A, 1B and 1C are manufacturing process views each illustrating an embodiment of a manufacturing method of a solid-state image pickup apparatus according to the present invention.

FIGS. 2D, 2E and 2F are manufacturing process views each illustrating the embodiment of the manufacturing method of the solid-state image pickup apparatus according to the present invention.

FIGS. 3G, 3H and 3I are manufacturing process views each illustrating the embodiment of the manufacturing method of the solid-state image pickup apparatus according to the present invention.

FIG. 4 is a conceptual diagram illustrating an imaging system to which the solid-state image pickup apparatus according to the present invention is applied.

### DESCRIPTION OF THE EMBODIMENTS

Preferred embodiments of the present invention will now be described in detail in accordance with the accompanying drawings.

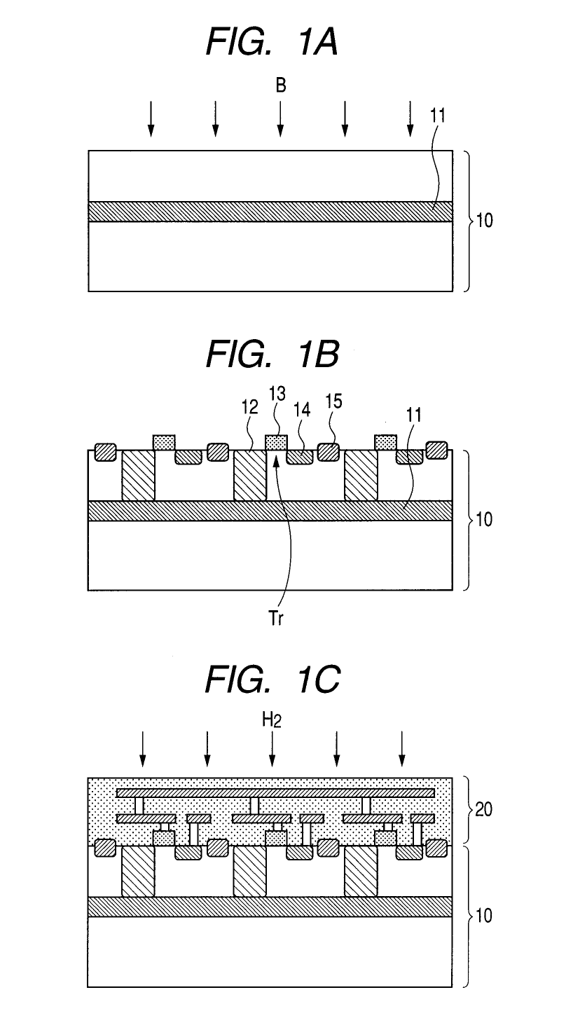

Hereinafter, embodiments of the present invention are described with reference to FIGS. 1A to 4.

### First Embodiment

FIGS. 1A to 1C are manufacturing process views each illustrating an embodiment of a manufacturing method of a solid-state image pickup apparatus according to the present invention.

In FIG. 1A, high concentration impurities of a first conductivity type are ion-implanted into a semiconductor substrate having the first conductivity type according to an ion implantation method, to thereby form therein a first semiconductor region of the first conductivity type which is uniformly highly doped at a predetermined depth from a first surface (front surface) of the semiconductor substrate. A semiconductor substrate 10 is made of, for example, p-type silicon, and a high concentration first semiconductor region 11 of the first conductivity type is a p⁺-type semiconductor region. The p⁺-type first semiconductor region 11 is formed by ion-implanting boron (B) into an entire surface of the semiconductor substrate. For ion implantation conditions, the dosage is set to 1×10¹⁴ cm⁻² and the acceleration energy is set to 3.4 MeV. For a range of the ion implantation conditions, the dosage can be 2×10¹¹ to 1×10¹⁴ cm⁻² (inclusive) and the acceleration energy can be 2.0 to 3.4 MeV (inclusive). When ions are implanted into the semiconductor substrate under these implantation conditions, it is possible to optimize a thickness of a photoelectric conversion region 12 in a light incident direction, the photoelectric conversion region 12 generating electric charges according to incident light. It is particularly efficient to implant ions into the entire surface of the semiconductor substrate, in order to enhance the planarization of a processed surface in a removing step to be performed later by reducing a thickness of the semiconductor substrate. In addition, according to the ion implantation method, the distribution of impurity concentration in a thickness direction is controllably formed depending on the ion implantation conditions, and hence the ion implantation method is particularly efficient in order to enhance the planarization of the processed surface in the removing step to be performed later by reducing the thickness of the semiconductor substrate. The photoelectric conversion region 12 is, for example, a photodiode. Under the above-mentioned implantation conditions, the high concentration first semiconductor region (p⁺-type semiconductor region) 11 is formed so as to have a center thereof at a depth of about 2.8 to 4.3 μm from the first surface of the semiconductor substrate 10. The photoelectric conversion region 12 is formed as an n-type semiconductor region of a second conductivity type opposite to the first conductivity type, and accumulates electrons. The photoelectric conversion region 12 is formed between the high concentration first semiconductor region 11 and the first surface of the semiconductor substrate 10. It should be noted that the first conductivity type is assumed as a p-type and the second conductivity type is assumed as an n-type, but the conductivity types may be inverted. In this case, the high concentration first semiconductor region is of an n⁺-type, and the photoelectric conversion region of the second conductivity type is of the p-type. In forming the n⁺-type semiconductor region, the ion implantation conditions such as the dosage and the acceleration energy are appropriately selected in consideration of a depth of the photoelectric conversion region 12. The thickness of the photoelectric conversion region 12 is controlled in view of the following fact. That is, the sensitivity or the saturation amount of electric charges decreases when the thickness is excessively small, whereas a high operating voltage for a transistor is necessary to sufficiently transfer the electric charges generated in the photoelectric conversion region 12, that is, electric power consumed by the solid-state image pickup apparatus becomes higher, when the thickness is excessively large. It should be noted that, in the above-mentioned example, for the substrate formation, ions are implanted into the semiconductor substrate, to thereby form the high concentration first semiconductor region, but alternative forming methods may be adopted. According to the first alternative method, an epitaxial layer as the high concentration first semiconductor region of the first conductivity type is formed on the semiconductor substrate of the first conductivity type, and another epitaxial layer as a second semiconductor region of an impurity concentration lower than that of the first semiconductor region or of a conductivity type different from that of the first semiconductor region is formed thereon. According to the second alternative method, an ion-implanted layer as the high concentration first semiconductor region of the first conductivity type is formed inside the semiconductor substrate of the first conductivity type, and an epitaxial layer as the second semiconductor region of an impurity concentration lower than that of the first semiconductor region or of a conductivity type different from that of the first semiconductor region is formed thereon. The epitaxial layer as the second semiconductor region may be formed so as to have a uniform impurity concentration, or may be formed so as to have an impurity concentration which becomes lower along with the growth of the epitaxial layer. In the case of using the epitaxial layer, a growth surface thereof corresponds to the first surface, and the photoelectric conversion region is formed on the epitaxial layer which is formed on the semiconductor substrate.

The substrate including the high concentration impurity region of the first conductivity type is prepared according to the various forming methods as described above, and then the manufacturing process proceeds to a subsequent step of forming the photoelectric conversion region constituting a circuit. Hereinafter, description is given of a method of manufacturing the solid-state image pickup apparatus with the use of the semiconductor substrate 10 illustrated in FIG. 1A.

After the preparation of the substrate, as illustrated in FIG. 1B, the circuit including the photoelectric conversion region 12 is formed in the semiconductor substrate 10. The circuit including the photoelectric conversion region includes the photoelectric conversion region 12, a floating diffusion region 14, a transfer transistor Tr, an amplifier transistor (not shown) and a reset transistor (not shown). In addition, an element isolation layer 15 is formed so as to isolate the photoelectric conversion region 12 from other photoelectric conversion regions. The transfer transistor Tr transfers electric charges from the photoelectric conversion region 12 to the floating diffusion region 14 by the control of a voltage at a gate electrode 13. The photoelectric conversion region 12 includes the n-type semiconductor region of the second conductivity type opposite to the first conductivity type. It is desirable to form a semiconductor region of a conductivity type opposite to that of the photoelectric conversion region 12 on the first surface side of the photoelectric conversion region 12, because a dark current can be suppressed.

Next, as illustrated in FIG. 1C, a wiring layer 20 is formed on the first surface (front surface) of the semiconductor substrate 10, and a hydrogen sintering process is performed. The hydrogen sintering process improves an interface state between the front surface of a silicon substrate as the semiconductor substrate 10 and an insulating film, and also improves electric contact between the silicon substrate and metal wiring made of aluminum or the like, which enables obtaining an excellent image.

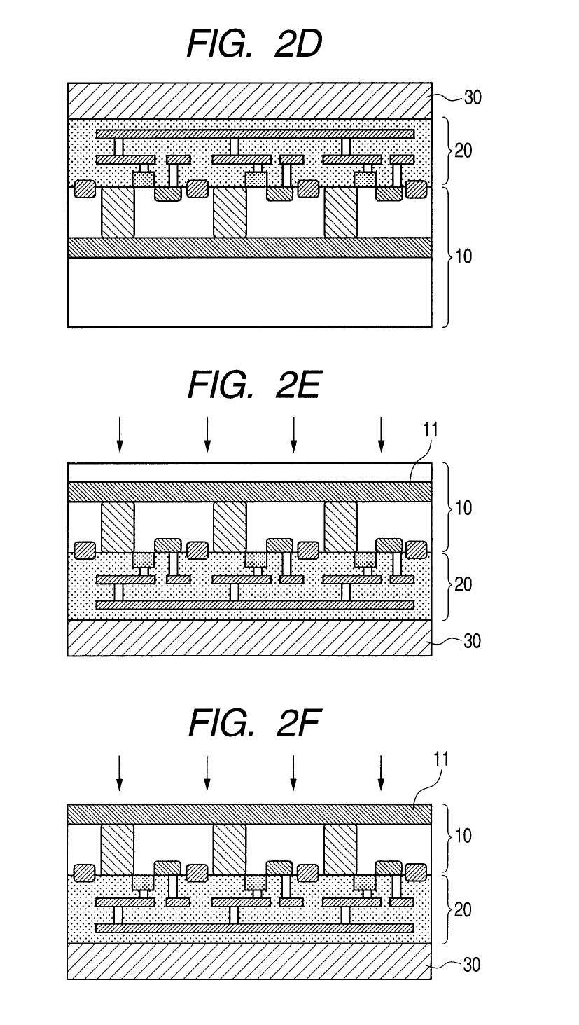

Next, as illustrated in FIG. 2D, a support substrate 30 is bonded to the wiring layer 20. Then, for a subsequent step of polishing the semiconductor substrate 10, the substrate is turned upside down so that the support substrate faces downward.

Next, as illustrated in FIG. 2E, a first removing step is performed by reducing a thickness of the semiconductor substrate 10 according to a mechanical polishing (MP) process or a chemical mechanical polishing (CMP) process. A second surface (back surface) of the semiconductor substrate 10 is opposite to the first surface, and faces upward in FIG. 2E. In order to leave 4.3 μm corresponding to the depth of the high concentration first semiconductor region 11 of the first conductivity type and a film thickness to be removed in a subsequent second removing step, the first removing step is performed so that the thickness of the semiconductor substrate 10 becomes 5 to 6 μm. In the case where the thickness of the semiconductor substrate 10 before the removing step is measured in advance, polishing is performed by controlling the amount of displacement of a polishing apparatus and a polishing time length. If the first removing step is performed with the polishing time length being fixed, the first removing step can be simplified. A processing speed in the first removing step is higher than that in the second removing step to be performed thereafter, for the reason of enhancing the throughput of the manufacturing process.

Next, as illustrated in FIG. 2F, the second removing step is performed by reducing the thickness of the semiconductor substrate 10 according to an eddy current CMP process with the high concentration first semiconductor region 11 of the first conductivity type being used as an etching stopper. In the eddy current CMP process, an etching end in the removing step is detected according to a change in electrical resistivity corresponding to the concentration of impurities contained in the semiconductor substrate 10. In the case where the eddy current CMP process is performed with the high concentration ion-implanted first semiconductor region 11 of the first conductivity type being used as the etching stopper, the thickness of the semiconductor substrate 10 can be controlled with high accuracy. Further, the semiconductor substrate having satisfactory planarization can be formed according to the eddy current CMP process. Accordingly, a formation area of the photoelectric conversion region 12 in the thickness direction from the back surface of the semiconductor substrate 10 becomes uniform over an entire region of the semiconductor substrate 10. According to the method disclosed in Japanese Patent Application Laid-Open No. 2005-353996 in which the etching end is detected based on the buried layer formed in a part of the silicon substrate, to thereby end the etching process, the planarization of the etched surface (the back surface used as the light incident side) is impaired, and fluctuations in thickness within the plane of the silicon substrate occur. The photoelectric conversion region is formed at a uniform depth within the plane from the wiring layer of the semiconductor substrate, and if the planarization of the back surface used as the light incident side is impaired, the depth of the photoelectric conversion region from the back surface differs within the plane, which thus causes fluctuations in sensitivity within the plane. Accordingly, it is efficient to use the high concentration first semiconductor region 11 of the first conductivity type as the etching stopper, in order to suppress characteristic fluctuations within the plane and obtain an excellent image quality. In addition, the high concentration first semiconductor region 11 of the first conductivity type functions as an inverted surface layer for preventing an end portion of the photoelectric conversion region 12 from being exposed on the second surface (back surface) of the semiconductor substrate, and hence the dark current can be reduced. In order to cause the first semiconductor region 11 to function as the inverted surface layer, an impurity concentration of the high concentration first semiconductor region of the first conductivity type, which is exposed when the second removing step by reducing the thickness of the semiconductor substrate is ended, is controlled to be 10¹⁷ to 10²⁰ cm⁻³ (inclusive).

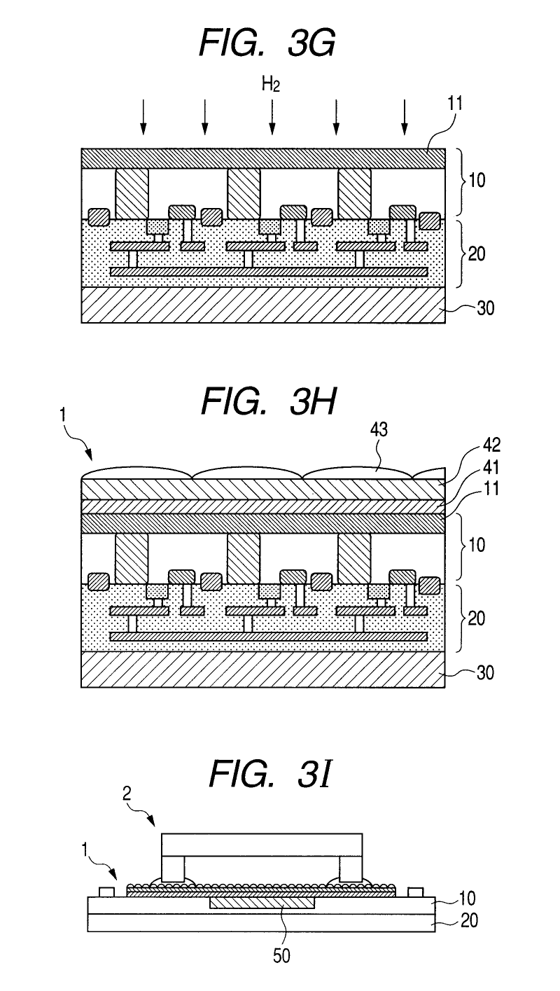

Next, as illustrated in FIG. 3G, the hydrogen sintering process is performed. As a result, it is possible to improve an interface state of an exposed surface of the high concentration first semiconductor region 11 of the first conductivity type after the second removing step. Accordingly, it is possible to further reduce an influence of electric charges to be a noise source, on the photoelectric conversion region.

Next, as illustrated in FIG. 3H, a passivation film 41 is formed on the back surface of the semiconductor substrate 10 whose thickness is reduced, and a color filter 42 and a microlens 43 are provided thereon, to thereby form a solid-state image pickup apparatus 1. The passivation film 41 is formed of a silicon nitride film or a silicon oxide film. The color filter is formed of a material of a color corresponding to each photoelectric conversion region 12.

Moreover, as illustrated in FIG. 3I, a transparent cover member 2 is fixed to the solid-state image pickup apparatus illustrated in FIG. 3H, to thereby seal a light receiving region 50.

As described above, the removing step is performed on the semiconductor substrate a plurality of times. Accordingly, it is possible to improve at the same time both of the throughput of the manufacturing process and the planarization of the semiconductor substrate after the removing steps, which enables realizing the solid-state image pickup apparatus capable of obtaining an excellent image.

### Second Embodiment

Next, a second embodiment is described. The present embodiment is different from the first embodiment in that the second removing step illustrated in FIG. 2F is performed according to an etching process.

A dry etching process or a wet etching process is adopted as the etching process.

Examples of an etching gas for the dry etching process include CF₄, SF₆, NF₃, SiF₄, BF₃, XeF₂, ClF₃ and SiCl₄. Similarly to the eddy current CMP process in the first embodiment, also in the dry etching process, the high concentration first semiconductor region 11 of the first conductivity type in which the impurity concentration of the semiconductor substrate 10 changes is used as the etching stopper, so that the thickness of the semiconductor substrate 10 is controlled with high accuracy and the planarization thereof is enhanced.

In addition, the wet etching process is an alkaline wet etching process. Examples of an etching solution therefor include: TMAH (tetramethylammonium hydroxide); a mixed solution of KOH (potassium hydroxide), water and IPA (isopropyl alcohol); and EPW (ethylenediamine pyrocatechol water). All of the etchants have an etching selectivity between low concentration p-type silicon and high concentration p-type silicon, and the high concentration first semiconductor region 11 of the first conductivity type functions as the etching stopper in the etching process of the silicon substrate, so that the thickness of the semiconductor substrate 10 is controlled with high accuracy. Accordingly, the planarization of the semiconductor substrate is satisfactory. An etching rate of p⁻ to p⁺ (p⁻/p⁺) of each of the etchants at 80° C. is approximately 10 for TMAH, approximately 200 for the mixed solution of KOH, water and IPA, and approximately 1,000 for EPW, and hence, in the case of using EPW, the thickness of the semiconductor substrate 10 is controlled with the highest accuracy. In order to cause the high concentration first semiconductor region of the first conductivity type to function as the inverted surface layer, the impurity concentration of the high concentration first semiconductor region of the first conductivity type, which is exposed when the second removing step by reducing the thickness of the semiconductor substrate is ended, is controlled to be 10¹⁷ to 10²⁰ cm⁻³ (inclusive).

### Third Embodiment

Next, a third embodiment is described. The present embodiment is different from the first embodiment in that the second removing step illustrated in FIG. 2F is performed according to a PACE (Plasma Assisted Chemical Etching) process.

The PACE process is a process of planarizing the semiconductor substrate while locally etching the surface of the semiconductor substrate with a plasma gas. Accordingly, the thickness of the semiconductor substrate 10 is controlled with high accuracy, and the planarization thereof is satisfactory, which thus enables obtaining an excellent image. In order to cause the high concentration first semiconductor region of the first conductivity type to function as the inverted surface layer, the impurity concentration of the high concentration first semiconductor region of the first conductivity type, which is exposed when the second removing step by reducing the thickness of the semiconductor substrate is ended, is controlled to be 10¹⁸ to 10¹⁹ cm⁻³ (inclusive).

### Fourth Embodiment

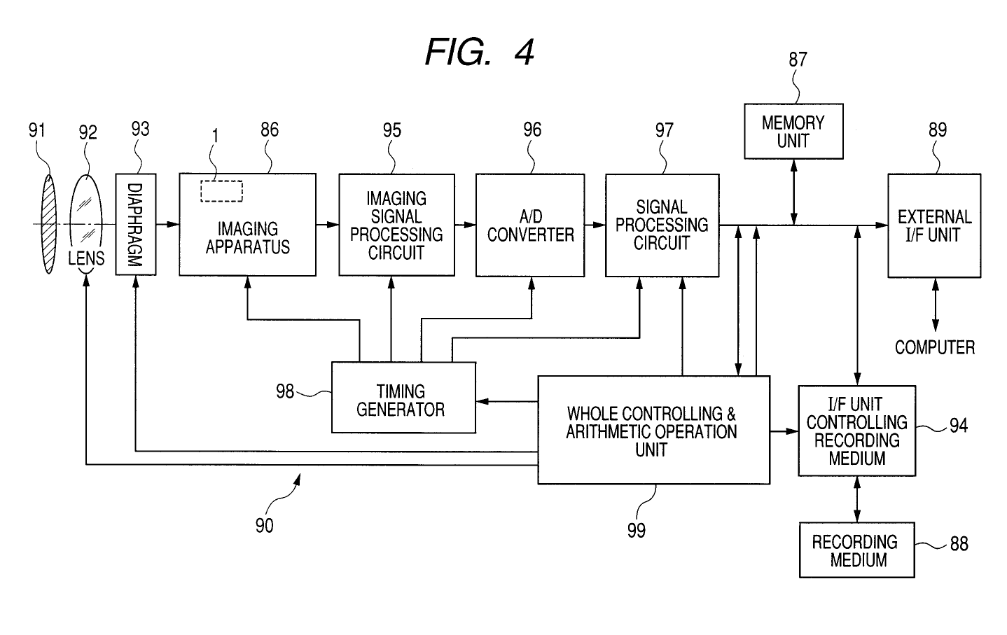

Next, an example of an imaging system to which the solid-state image pickup apparatus according to the present invention is applied is illustrated in FIG. 4.

As illustrated in FIG. 4, an imaging system 90 mainly includes an optical system, an imaging apparatus 86 and a signal processing unit. The optical system mainly includes a shutter 91, an imaging lens 92 and a diaphragm 93. The imaging apparatus 86 includes the solid-state image pickup apparatus 1. The signal processing unit mainly includes an imaging signal processing circuit 95, an A/D converter 96, an image signal processing circuit 97, a memory unit 87, an external I/F unit 89, a timing generator 98, a whole controlling and arithmetic operation unit 99, a recording medium 88 and an I/F unit 94 controlling the recording medium. It should be noted that the signal processing unit does not necessarily include the recording medium 88.

The shutter 91 is disposed on the near side of the imaging lens 92 on an optical path, and controls exposure.

The imaging lens 92 refracts incident light, and forms an object image on an imaging plane of the solid-state image pickup apparatus 1 of the imaging apparatus 86.

The diaphragm 93 is disposed between the imaging lens 92 and the solid-state image pickup apparatus 1 on the optical path, and adjusts an amount of the light which passes through the imaging lens 92 and then is guided to the solid-state image pickup apparatus 1.

The solid-state image pickup apparatus 1 of the imaging apparatus 86 converts into an image signal the object image which is formed on the imaging plane of the solid-state image pickup apparatus 1. The imaging apparatus 86 reads out the image signal from the solid-state image pickup apparatus 1 and outputs the read-out image signal.

The imaging signal processing circuit 95 is connected to the imaging apparatus 86, and processes the image signal output from the imaging apparatus 86.

The A/D converter 96 is connected to the imaging signal processing circuit 95, and converts into a digital signal the processed image signal (analog signal) output from the imaging signal processing circuit 95.

The image signal processing circuit 97 is connected to the A/D converter 96, and performs various arithmetic operations such as correction on the image signal (digital signal) output from the A/D converter 96, to thereby generate image data. The generated image data is supplied to the memory unit 87, the external I/F unit 89, the whole controlling and arithmetic operation unit 99 and the I/F unit 94 controlling the recording medium.

The memory unit 87 is connected to the image signal processing circuit 97, and stores the image data output from the image signal processing circuit 97.

The external I/F unit 89 is connected to the image signal processing circuit 97. With this configuration, the image data output from the image signal processing circuit 97 is transferred to an external device (a personal computer or the like) via the external I/F unit 89.

The timing generator 98 is connected to the imaging apparatus 86, the imaging signal processing circuit 95, the A/D converter 96 and the image signal processing circuit 97. With this configuration, the timing generator supplies a timing signal to the imaging apparatus 86, the imaging signal processing circuit 95, the A/D converter 96 and the image signal processing circuit 97. Further, the imaging apparatus 86, the imaging signal processing circuit 95, the A/D converter 96 and the image signal processing circuit 97 each operate in synchronization with the timing signal.

The whole controlling and arithmetic operation unit 99 is connected to the timing generator 98, the image signal processing circuit 97 and the I/F unit 94 controlling the recording medium, and wholly controls the timing generator 98, the image signal processing circuit 97 and the I/F unit 94 controlling the recording medium.

The recording medium 88 is removably connected to the I/F unit 94 controlling the recording medium. With this configuration, the image data output from the image signal processing circuit 97 is recorded in the recording medium 88 via the I/F unit 94 controlling the recording medium.

With the configuration as described above, when an excellent image signal can be obtained in the solid-state image pickup apparatus 1, an excellent image (image data) can be also obtained.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-278009, filed Dec. 7, 2009, which is hereby incorporated by reference herein in its entirety.

1. A manufacturing method of a solid-state image pickup apparatus comprising:
a step of forming a first semiconductor region of a first conductivity type in a semiconductor substrate, according to an ion implantation method from a side of a first surface of the semiconductor substrate;
a step of forming a plurality of photoelectric conversion regions between the first semiconductor region and the first surface of the semiconductor substrate;
a first removing step by polishing the semiconductor substrate from a side of a second surface of the semiconductor substrate; and
a second removing step by reducing a thickness of the semiconductor substrate from the side of the second surface of the semiconductor substrate, in a speed lower than that of the first removing step, after the first removing step, wherein
the second removing step continues at least before the first semiconductor region is exposed.

2. The manufacturing method according to claim 1, further comprising a step of forming, between the first semiconductor region and the second surface in the semiconductor substrate, a second semiconductor region of an impurity concentration lower than that of the first semiconductor region or of a conductivity type different from the first conductivity type, at least before the step of forming a plurality of photoelectric conversion regions.

3. The manufacturing method according to claim 1, wherein the second removing step is performed to expose the first semiconductor region as an inverted surface layer arranged at a side of the semiconductor substrate opposite to the side of the first surface at which each of the plurality of photoelectric conversion regions is arranged.

4. The manufacturing method according to claim 1, further comprising a step of subjecting a region in which the first semiconductor region is exposed to hydrogen sintering process, after the second removing step.

5. The manufacturing method according to claim 1, wherein the step of forming the first semiconductor region is conducted according to the ion implantation method under a condition such that dosage 2×10¹¹-1×10¹⁴ cm⁻², and an acceleration energy 2.0-3.4 Mev.

6. The manufacturing method according to claim 1, wherein the second removing step is conducted such that the first semiconductor region exposed contains an impurity concentration 10¹⁷-10²⁰ cm⁻³.

7. The manufacturing method according to claim 1, wherein the first removing step is conducted according to MP or CMP process.

8. The manufacturing method according to claim 1, wherein the second removing step is conducted according to an eddy current CMP process.

9. The manufacturing method according to claim 1, wherein the second removing step is conducted according to a dry or wet etching process.

10. The manufacturing method according to claim 1, wherein the second removing step is conducted according to a PACE process.
